(19) United States
(12) Patent Application Publication
(10) Pub. No.: US 2026/0343871 A1
(43) Pub. Date: Oct. 29, 2026

(54) DYNAMIC RANDOM ACCESS MEMORY, FORMING METHOD THEREOF AND MEMORY SYSTEM

(71) Applicant: Yangtze Memory Technologies Co., Ltd., Wuhan (CN)

(72) Inventors: Zhaohong LI, Wuhan (CN); Yu WANG, Wuhan (CN)

(21) Appl. No.: 19/333,653

(22) Filed: Sep. 19, 2025

(30) Foreign Application Priority Data
Apr. 29, 2025 (CN) 202510559026.8

(51) Int. Cl. H10B 12/00; G11C 11/4074; H10B 80/00; H10W 90/00

(52) U.S. Cl. CPC H10B 12/50; G11C 11/4074; H10B 80/00; H10W 90/00

(57) ABSTRACT

A dynamic random access memory, a forming method thereof and a memory system are provided. The dynamic random access memory includes a first semiconductor structure and a second semiconductor structure that are stacked along a first direction. The first semiconductor structure includes a memory cell array and a first capacitor structure that is configured as a capacitor of a charge pump circuit. The second semiconductor structure includes a peripheral circuit that includes a voltage regulation circuit of the charge pump circuit.

### CROSS-REFERENCE TO RELATED APPLICATIONS

This application claims priority to Chinese Patent Application No. 202510559026.8, filed on Apr. 29, 2025, which is hereby incorporated by reference in its entirety.

### TECHNICAL FIELD

The present disclosure relates to the field of semiconductor technology, for example, to a dynamic random access memory, a forming method thereof, and a memory system.

### BACKGROUND

With the continuous development of science and technology today, semiconductor devices are widely applied to various electronic devices and electronic products. For example, a dynamic random access memory (DRAM), as a volatile memory, is a common semiconductor memory device in a computer.

### SUMMARY

According to a first aspect of the examples of the present disclosure, there is provided a dynamic random access memory, comprising: a first semiconductor structure and a second semiconductor structure stacked along a first direction; wherein the first semiconductor structure comprises a memory cell array and a first capacitor structure which is configured as a capacitor of a charge pump circuit; and the second semiconductor structure comprises a peripheral circuit which comprises a voltage regulation circuit of the charge pump circuit.

In some implementations, the dynamic random access memory comprises a first memory area, a first peripheral area and a second memory area arranged along a second direction, and the first peripheral area is located between the first memory area and the second memory area; the memory cell array is located in the first memory area and the second memory area; and the second direction is perpendicular to the first direction.

In some implementations, the first capacitor structure is located in the first peripheral area.

In some implementations, the voltage regulation circuit is located in the first peripheral area.

In some implementations, the dynamic random access memory further comprises a second peripheral area; the first memory area, the first peripheral area and the second memory area are located on a same side of two opposite sides of the second peripheral area along a third direction; the first capacitor structure is located in the second peripheral area; and the third direction is perpendicular to both the first direction and the second direction.

In some implementations, the voltage regulation circuit is located in the second peripheral area.

In some implementations, the voltage regulation circuit at least partially overlaps with the first capacitor structure in a view perpendicular to the first direction.

In some implementations, the memory cell array comprises a plurality of memory cells, the memory cell comprises a transistor structure and a second capacitor structure, and the first capacitor structure and the second capacitor structure have a same structure.

In some implementations, the charge pump circuit comprises the voltage regulation circuit and a capacitor circuit; the voltage regulation circuit comprises a plurality of voltage regulation sub-circuits, and the capacitor circuit comprises a plurality of capacitor sub-circuits; and the capacitor sub-circuit at least partially overlap with the correspondingly connected voltage regulation sub-circuit in a view perpendicular to the first direction.

In some implementations, the voltage regulation circuit comprises N voltage regulation sub-circuits sequentially connected in series, an input end of a first voltage regulation sub-circuit is connected to a voltage input end, and an output end of an N-th voltage regulation sub-circuit is connected to a voltage output end; and N is an integer greater than 1.

In some implementations, the voltage regulation sub-circuit includes a diode.

In some implementations, the capacitor circuit comprises (N−1) capacitor sub-circuits, and the capacitor sub-circuit comprises at least one first capacitor structure; and a first end of each of the (N−1) capacitor sub-circuits is connected to an output end of each of first (N−1) voltage regulation sub-circuits in a one-to-one correspondence.

In some implementations, a second end of an odd-numbered capacitor sub-circuit of the (N−1) capacitor sub-circuits is connected to a first clock signal end, and a second end of an even-numbered capacitor sub-circuit of the (N−1) capacitor sub-circuits is connected to a second clock signal end; and a first clock signal provided by the first clock signal end and a second clock signal provided by the second clock signal end are complementary clock signals.

In some implementations, the capacitor sub-circuit comprises M first capacitor structures connected in parallel, and M is an integer greater than or equal to 2.

In some implementations, M is equal to 2.

In some implementations, the first semiconductor structure further comprises a first bonding layer, which comprises a first bonding structure, and is located between the memory cell array and the second semiconductor structure, and between the first capacitor structure and the second semiconductor structure; and the second semiconductor structure further comprises a second bonding layer, which comprises a second bonding structure and is located between the peripheral circuit and the first semiconductor structure.

In some implementations, the first semiconductor structure further comprises a first interconnection structure located between the first capacitor structure and the first bonding layer; the second semiconductor structure further comprises a second interconnection structure located between the voltage regulation circuit and the second bonding layer; and the first capacitor structure is connected to the voltage regulation circuit through the first interconnection structure, the first bonding structure, the second bonding structure, and the second interconnection structure.

According to a second aspect of the examples of the present disclosure, there is provided a memory system, comprising a memory controller, and the dynamic random access memory according to any one of the above implementations, wherein the memory controller is coupled with the dynamic random access memory and configured to control the dynamic random access memory.

According to a third aspect of the examples of the present disclosure, there is provided a forming method of a dynamic random access memory, comprising: forming a first semiconductor structure and a second semiconductor structure stacked along a first direction; wherein the first semiconductor structure comprises a memory cell array and a first capacitor structure which is configured as a capacitor of a charge pump circuit; and the second semiconductor structure comprises a peripheral circuit which comprises a voltage regulation circuit of the charge pump circuit.

In some implementations, the forming the first semiconductor structure and the second semiconductor structure stacked along the first direction comprises: forming the first capacitor structure while forming a second capacitor structure of a memory cell of the memory cell array.

In the disclosed examples, the first capacitor structure in the first semiconductor structure is configured as the capacitor of the charge pump circuit, and no metal capacitor or MOSFET capacitor needs to be additionally formed in the second semiconductor structure where the peripheral circuit is located, so that the area of the second semiconductor structure where the peripheral circuit is located can be saved on the basis of meeting the high-current capability of the charge pump, which is beneficial for the miniaturization trend of the dynamic random access memory.

### BRIEF DESCRIPTION OF THE DRAWINGS

FIG. 1A is a block diagram of the composition of an example electronic device according to an example of the present disclosure;

FIG. 1B is a schematic diagram of the composition of an example electronic device according to an example of the present disclosure;

FIG. 2A is a block diagram of the composition of an example solid state drive (SSD) according to an example of the present disclosure;

FIG. 2B is a block diagram of the composition of an example main memory according to an example of the present disclosure;

FIG. 3 is a schematic diagram of the composition structure of an example dynamic random access memory according to an example of the present disclosure;

FIG. 4 is a schematic diagram of the connection relationships among word lines, bit lines and memory cells of an example dynamic random access memory according to an example of the present disclosure;

FIG. 5 is a first schematic diagram of the frame structure of a dynamic random access memory according to an example of the present disclosure;

FIG. 6 is a first schematic diagram of the area distribution of a dynamic random access memory according to an example of the present disclosure;

FIG. 7 is a first schematic diagram of the area distribution of a second semiconductor structure according to an example of the present disclosure;

FIG. 8 is a second schematic diagram of the area distribution of a dynamic random access memory according to an example of the present disclosure;

FIG. 9 is a second schematic diagram of the area distribution of a second semiconductor structure according to an example of the present disclosure;

FIG. 10 is a schematic diagram of a relationship between an equivalent circuit of a charge pump circuit and a first semiconductor structure and a second semiconductor structure according to an example of the present disclosure;

FIG. 11 is a schematic diagram of an equivalent circuit of a charge pump circuit according to an example of the present disclosure;

FIG. 12 is a schematic diagram of an equivalent circuit of a Dickson charge pump circuit when N is 3;

FIG. 13 is a second schematic diagram of the frame structure of a dynamic random access memory according to an example of the present disclosure;

FIG. 14 is a schematic three-dimensional structural diagram of a dynamic random access memory according to an example of the present disclosure;

FIG. 15 is a schematic flowchart of a forming method of a dynamic random access memory according to an example of the present disclosure.

### DETAILED DESCRIPTION

Implementations of the present disclosure will be described in more detail below with reference to the accompanying drawings. Although the implementations of the present disclosure are shown in the drawings, it should be understood that the present disclosure may be implemented in various forms and should not be limited by the implementations set forth herein. Rather, these implementations are provided so that the present disclosure can be more thoroughly understood, and the scope of the disclosure can be completely conveyed to those skilled in the art.

In the following description, numerous details are given in order to provide a more thorough understanding of the present disclosure. However, it will be apparent to those skilled in the art that the present disclosure may be practiced without one or more of these details. In other examples, to avoid confusion with the present disclosure, some technical features known in the art are not described; that is, not all of the features of actual examples are described herein, and well-known functions and structures are not described in detail.

In the drawings, same reference number refers to same element throughout.

It should be understood that spatial relationship terms such as “under”, “below”, “lower”, “beneath”, “above”, “upper”, and the like may be used herein for ease of description to describe one element or feature's relationship to another element or feature shown in the figures. It should be appreciated that the spatial relationship terms are intended to include different orientations of the device in use and operation in addition to the orientation shown in the figures. For example, if a device in the figures is flipped, then an element or feature described as being “below” or “beneath” or “under” another element or feature will be oriented “on” the another element or feature. Thus, the example terms “below” and “under” can include both upper orientation and lower orientation. The device may additionally be oriented (rotated 90 degrees or another orientation) and the spatial description terms used herein are interpreted accordingly.

The terminology used herein is for the purpose of describing examples only and not as a limitation of the present disclosure. As used herein, the singular forms “a,” “an,” and “the” are also intended to include the plural forms unless the context clearly indicates otherwise. It should also be understood that the terms “consisting of” and/or “including,” when used in this specification, determine the presence of stated features, integers, steps, operations, elements and/or components, but do not preclude the presence or addition of one or more other features, integers, steps, operations, elements, components and/or groups. As used herein, the term “and/or” includes any and all combinations of related listed items.

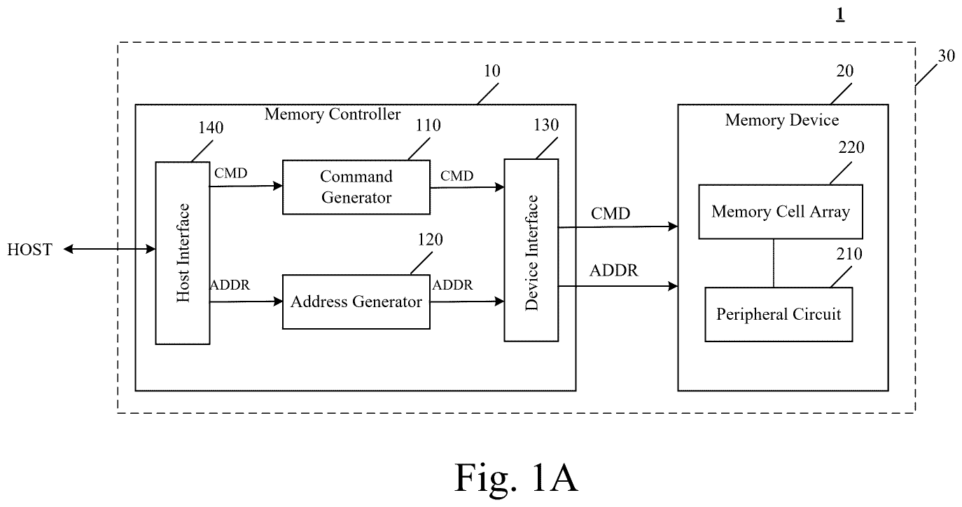

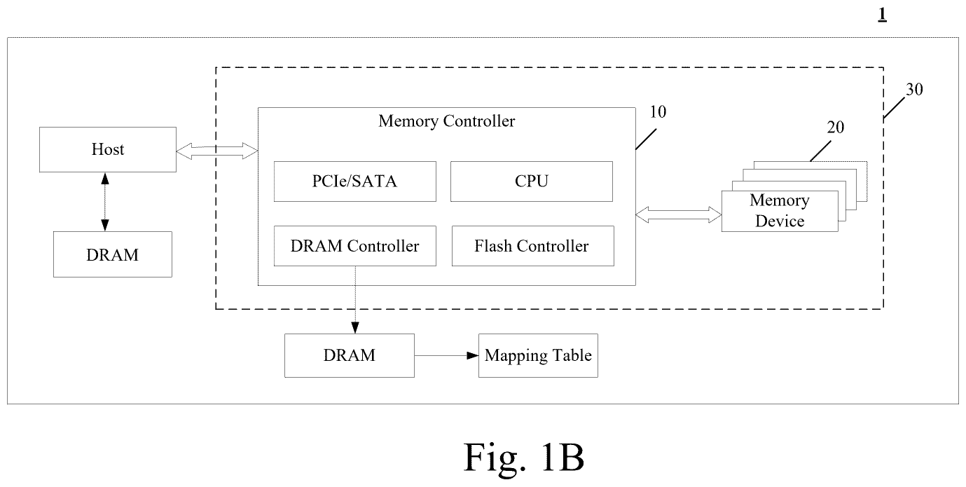

FIG. 1A illustrates a block diagram of the composition of an example electronic device according to an example of the present disclosure. The electronic device 1 may be a mobile phone, a desktop computer, a laptop computer, a tablet computer, a vehicle computer, a game console, a printer, a positioning device, a wearable electronic device, a smart sensor, a virtual reality (VR) device, an augmented reality (AR) device, or any other suitable electronic device having storage therein. As shown in FIG. 1A, the electronic device 1 may include a host HOST and a memory system 30 including a memory controller 10 and one or more memory device 20. The host HOST may be a processor (e.g., a central processing unit (CPU) or a graphic processing unit (GPU)) of the electronic device. The host HOST may be configured to send data to or receive data from the memory device 20. The memory controller 10 is coupled to the memory device 20 and the host HOST and is configured to control the memory device 20. The memory controller 10 may manage data stored in the memory device 20 and communicate with the host HOST.

The memory controller 10 may be configured to control operations of the memory device 20, such as read, erase, write, and refresh operations. In some implementations, the memory controller 10 is further configured to process an error correction code (ECC) on data read from or written to the memory device 20. The memory controller 10 may also perform any other suitable functions, such as formatting memory device 20.

In some examples, the memory controller 10 and the one or more memory device 20 may be integrated into various types of electronic devices, for example, the memory controller 10 may be integrated into a north bridge of a computer motherboard or directly integrated into a CPU of a computer, and a plurality of memory device 20 may be integrated into a memory module. That is, the memory system 30 may be implemented and packaged into different types of terminal electronic products.

The memory controller 10 may send/receive data to/from the host HOST, and may send a command CMD and an address ADDR to the memory device 20. The memory controller 10 may include a command generator 110, an address generator 120, a device interface 130, and a host interface 140. The host interface 140 may receive the command CMD and the address ADDR from the host HOST, the command generator 110 may generate an access command, a row hammer refresh command or the like by decoding the command CMD received from the host HOST, and may provide the access command and the row hammer refresh command to the memory device 20 through the device interface 130. The access command may be a signal instructing the memory device 20 to write or read data by accessing a row of the memory cell array 220 corresponding to the address ADDR. The row hammer refresh command may be a signal that commands the memory device 20 to perform an additional refresh operation on a word line adjacent to a word line that is densely accessed over a short period of time. In other words, the additional refresh operation may be performed on the word line adjacent to the word line accessed multiple times over a short period of time.

The address generator 120 in the memory controller 10 may generate a row address and a column address to be accessed in the memory cell array 220 by decoding the address ADDR received from the host interface 140. In addition, the memory device 20 may generate an address of a memory bank to be accessed when the memory cell array 220 includes a plurality of memory banks.

Further, the memory controller 10 may control memory operations such as writing and reading by providing various signals to the memory device 20 via the device interface 130. For example, the memory controller 10 may provide a write command to the memory device 20. The write command is configured to instruct the memory device 20 to perform a write operation to store data into the memory device 20.

In some examples, the memory device 20 includes a memory cell array 220 and a peripheral circuit 210; where the memory cell array 220 includes a plurality of memory banks, each memory bank includes a plurality of memory blocks, each memory block includes a plurality of rows of memory cells and a plurality of columns of memory cells, each row of memory cells is coupled with a corresponding word line, and each column of memory cells is coupled with a corresponding bit line. The peripheral circuit 210 may write data to or read data from the memory cell array 220 based on a command CMD and an address ADDR received from the memory controller 10, or may provide a control signal CTRL for refreshing the memory cells included in the memory cell array 220 to a row decoding circuit and a column decoding circuit. In other words, the peripheral circuit 210 may perform all operations to process data in the memory cell array 220. The peripheral circuit 210 may include a control circuit corresponding to each memory block, such as a sensing amplifier (SA), a word line driver (WLD), and the like; a control circuit corresponding to each memory bank, such as a row decoding circuit, a column decoding circuit, and the like; and a control circuit corresponding to all memory banks, such as a command buffer, a command decoder, an address buffer, a data input/output buffer, a mode register, and the like.

The memory device 20 may be a random access memory (RAM), such as dynamic random access memory (DRAM), synchronous DRAM (SDRAM), static RAM (SRAM), double data rate SDRAM (DDR SDRAM), DDR2 SDRAM, DDR3 SDRAM, phase change RAM (PRAM), magnetic RAM (MRAM), resistive RAM (RRAM), and the like. The following illustrates by using the DRAM only as an example.

FIG. 1B illustrates a schematic diagram of the composition of an example electronic device according to an example of the present disclosure. In some examples, a DRAM may belong to a structure outside the memory system 30, which may be directly connected to the host to serve as a main memory when the host runs, or the DRAM may also be embedded in the host. In some examples, the DRAM may belong to a structure outside the memory system 30, which may be coupled with the memory system 30 for use as a buffer memory, for example, for storing a mapping table. In some examples, the DRAM as the buffer memory may also be embedded in the memory controller 10. In some other examples, the DRAM may also belong to a part within the memory controller 10, for example, the DRAM as the buffer memory is embedded in the memory controller 10. In some examples, the DRAM may also belong to a part within the memory controller 10, such as a part in a DRAM controller, for controlling the memory device 20 to perform operations such as writing and reading. In some other examples, a stacking arrangement of a plurality of DRAM may be applied to a high bandwidth memory (HBM) architecture for use as a storage medium.

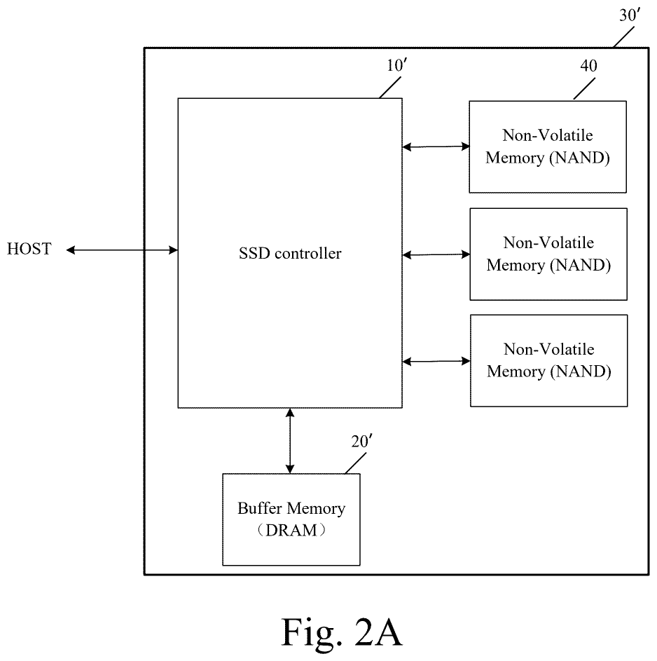

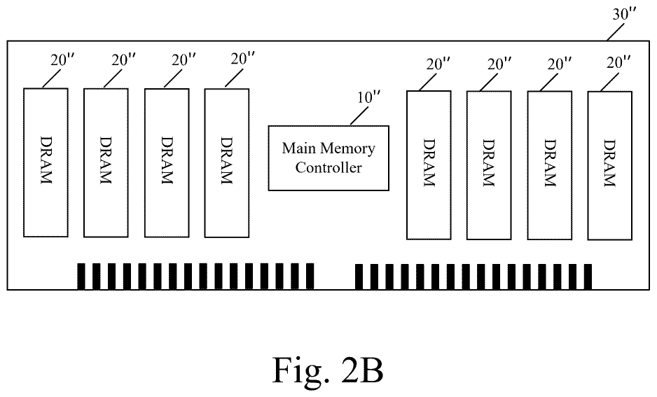

FIG. 2A is a block diagram of the composition of an example SSD according to an example of the present disclosure. Here, the SSD may be construed as one of the aforementioned memory systems in FIG. 1A and FIG. 1B, and in this example, the DRAM may be used as a buffer memory.

As shown in FIG. 2A, SSD 30′ may include an SSD controller 10′, a buffer memory 20′, and a non-volatile memory 40. The SSD controller 10′ may provide a physical connection between the host HOST and the SSD 30′. That is, the SSD controller 10′ may provide an interface between the host HOST and the SSD 30′ in a bus format of the host. The SSD controller 10′ may decode an instruction provided from the host HOST. The SSD controller 10′ may access the non-volatile memory 40 based on the decoding result. The buffer memory 20′ may temporarily store write data provided from the host HOST, or data read from the non-volatile memory 40. When the host HOST issues a read request, if the data present in the non-volatile memory 40 is cached, the buffer memory 20′ may support a cache function for providing the cached data directly to the host HOST. The data transfer rate through the bus format of the host (e.g., SATA or SAS) is much higher than that of a memory channel of the SSD 30′. That is, when the interface speed of the host is significantly high, the performance degradation due to speed differences can be minimized by providing a high-capacity buffer memory 20′. In addition, the buffer memory 20′ may store an address mapping table of the non-volatile memory 40. The buffer memory 20′ may include, but is not limited to, DRAM. The non-volatile memory 40 is provided as a storage medium of the SSD 30′. The non-volatile memory 40 may include, but is not limited to, a NAND-type memory.

FIG. 2B is a block diagram of the composition of an example main memory according to an example of the present disclosure; herein, the main memory may be construed as one of the foregoing memory systems in FIG. 1A, and in this example, the DRAM may be used as a storage medium.

As shown in FIG. 2B, the main memory 30″ is easily attachable or mountable to or detachable from the electronic device 1 through the illustrated interface. The main memory 30″ may include a plurality of volatile memories 20″ (e.g., DRAM) and a main memory controller 10″. The main memory 30″ may be configured to write data, store data, fetch (or, read) data, and/or erase data under a control of a processor of a computer. In some examples, the main memory controller 10″ may communicate with the DRAM using at least one communication protocol or technical standard associated with, for example, a dual in-line memory modules (DIMMs), a registered DIMMs (RDIMMs), a low-load DIMMs (LRDIMMs), a unregistered DIMMs (UDIMMs), etc.

It should be noted that both the buffer memory 20′ in FIG. 2A and the volatile memory 20″ in FIG. 2B are application scenarios of the memory device 20 in FIG. 1A.

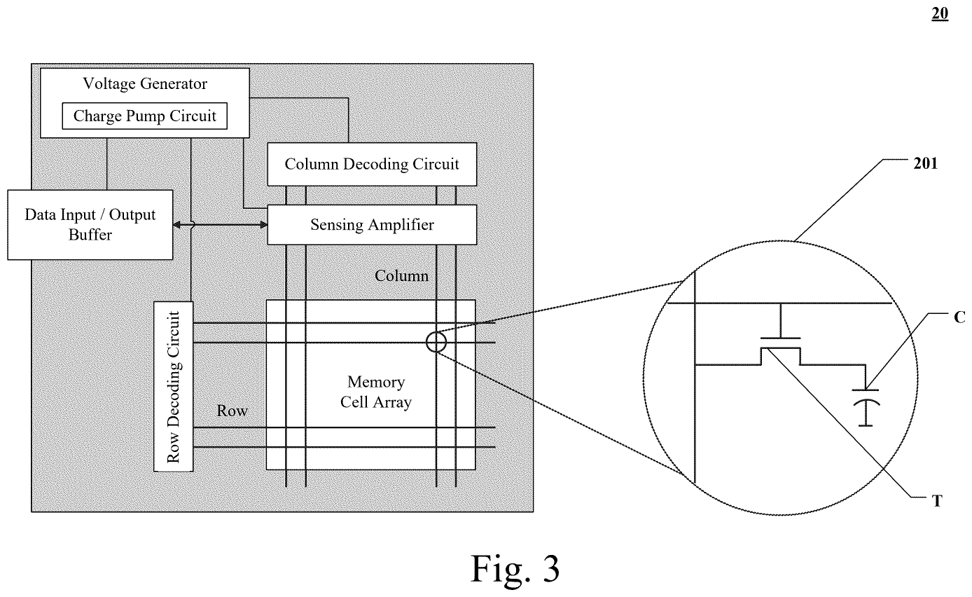

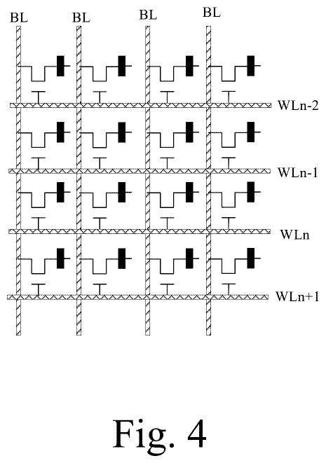

FIG. 3 is a schematic diagram of the composition structure of an example dynamic random access memory according to an example of the present disclosure; and FIG. 4 is a schematic diagram of the connection relationships among word lines, bit lines and memory cells of the example dynamic random access memory according to an example of the present disclosure.

The right side of FIG. 3 shows the circuit of a memory cell in DRAM. The DRAM includes at least one DRAM chip (die), each DRAM chip includes a memory cell array, the memory cell array includes a plurality of memory cells 201 arranged in an array, each memory cell 201 includes a transistor T and a capacitor C, and a main function principle of the memory cell is to use the quantity of charges stored in the capacitor to represent whether a binary bit is 1 or 0. The memory cells are arranged in an array and can be regarded as a typical mesh structure, and the mesh structure can be referred to FIG. 4. The memory cell array specifies an address with a row and a column. By specifying an intersection of the row and the column (by specifying a row address and a column address of the DRAM), the memory controller can independently access various memory cells in the DRAM chip, and read, write or refresh data stored therein.

The left side of FIG. 3 shows the memory cell array and a part of peripheral circuits in the DRAM. It should be noted that the row decoding circuit selects a word line to select a row of memory cells to be accessed in response to an address input to the row decoding circuit. The row decoding circuit decodes the input address and enables (activates) the word line corresponding to the decoded address. The column decoding circuit selects one or more bit lines to input output data to a portion of a row of memory cells corresponding to the selected word line. As shown in FIG. 3, the peripheral circuit further includes a voltage generator which may generate and adjust various voltages required inside the dynamic random access memory. For example, a high voltage (e.g., VPP) may be provided for the row decoding circuit to drive the selected word line, a reference voltage may be provided for the sense amplifier to detect and amplify the tiny signal on the bit line, a switch control voltage (e.g., VDD or negative voltage) may be provided for the column decoding circuit to connect the selected bit line with the data bus, and an interface voltage (e.g., VDDQ or high voltage VDDQ+, a voltage matched with the external system) may be provided for the data input/output buffer to make level compatibility between the dynamic random access memory and the external controller.

In order to achieve the write and refresh operations on the memory cells of the dynamic random access memory, it is necessary to provide a higher voltage than the normal operating voltage. The charge pump circuit in the voltage generator can convert a low voltage (such as VDD) into a required high voltage (such as VPP, VDDQ+), thereby providing sufficient charge for the memory cells of the dynamic random access memory, and the charge pump circuit has many advantages such as low power consumption, high integration level and stability, so that the charge pump circuit is widely used in the dynamic random access memory.

In some examples, the capacitor in the charge pump circuit uses a MOSFET capacitor or a metal capacitor in the peripheral circuit. In order to obtain a larger current capability, a capacitor with a larger size needs to be used, and the larger the current capability is, the larger the required capacitor size is, so that a larger area of the peripheral circuit is occupied, and an area occupied by the dynamic random access memory is larger, which is not conducive to the miniaturization development of the dynamic random access memory. With increasing requirements on the integration level of the memory, how to save the area of the memory becomes an urgent problem to be solved.

In this regard, the present disclosure proposes the following implementations.

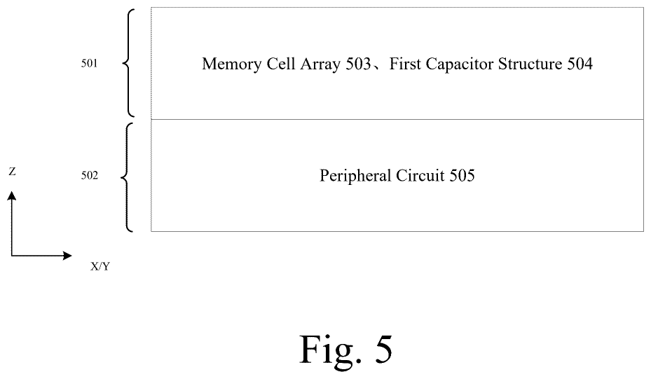

An example of the present disclosure provides a dynamic random access memory, and FIG. 5 is a schematic diagram of the frame structure of the dynamic random access memory according to the example of the present disclosure. As shown in FIG. 5, the dynamic random access memory includes: a first semiconductor structure 501 and a second semiconductor structure 502 stacked along a first direction; where the first semiconductor structure 501 includes a memory cell array 503 and a first capacitor structure 504, and the first capacitor structure 504 is configured as a capacitor of a charge pump circuit; the second semiconductor structure 502 includes a peripheral circuit 505 which includes a voltage regulation circuit of the charge pump circuit.

The first direction in an example of the present disclosure may be construed as a Z-axis direction in the drawings, the second direction may be construed as a Y-axis direction in the drawings, and the third direction may be construed as an X-axis direction in the drawings.

In an example of the present disclosure, the first capacitor structure 504 in the first semiconductor structure 501 is configured as the capacitor of the charge pump circuit, and there is no need to additionally form a metal capacitor or a MOSFET capacitor in the second semiconductor structure 502 where the peripheral circuit 505 is located, so that the area of the second semiconductor structure 502 where the peripheral circuit 505 is located can be saved on the basis of meeting the capability of large current of the charge pump, which is beneficial for the miniaturization development of the dynamic random access memory.

In an example of the present disclosure, the first semiconductor structure includes a memory cell array, the second semiconductor structure includes a peripheral circuit, and the first semiconductor structure and the second semiconductor structure are stacked along the first direction, so that the area occupied by the dynamic random access memory can be reduced.

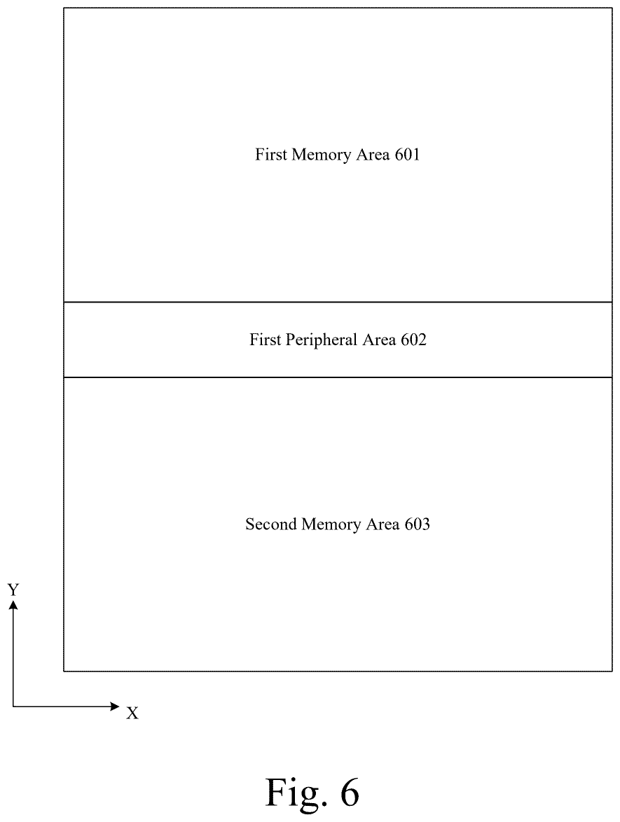

FIG. 6 is a first schematic diagram of the area distribution of a dynamic random access memory according to an example of the present disclosure.

In some examples, as shown in FIG. 6, the dynamic random access memory includes a first memory area 601, a first peripheral area 602 and a second memory area 603 arranged along a second direction, the first peripheral area 602 is located between the first memory area 601 and the second memory area 603; the memory cell array 503 is located in the first memory area 601 and the second memory area 603; and the second direction is perpendicular to the first direction.

In an example of the present disclosure, the dynamic random access memory includes a first memory area 601, a first peripheral area 602, and a second memory area 603 arranged along the Y-axis direction, and the memory cell array 503 is disposed in the first memory area 601 and the second memory area 603.

In some examples, the first capacitor structure 504 is located in the first peripheral area 602.

In an example of the present disclosure, the first capacitor structure 504 in the first semiconductor structure 501 is configured as the capacitor of the charge pump circuit, so that the area of the peripheral circuit can be saved; and the first capacitor structure 504 is disposed in an idle area in the first semiconductor structure 501, for example, the first capacitor structure 504 is located in the first peripheral area 602, so that the idle area of the first semiconductor structure 501 in the first peripheral area 602 can be fully utilized, which is beneficial for reducing the area occupied by the dynamic random access memory and beneficial for the miniaturization development of the dynamic random access memory.

In some examples, the voltage regulation circuit is located in the first peripheral area 602.

In an example of the present disclosure, the peripheral circuit in the second semiconductor structure 502 includes the voltage regulation circuit of the charge pump circuit, and the voltage regulation circuit is located in the second semiconductor structure 502 in the first peripheral area 602.

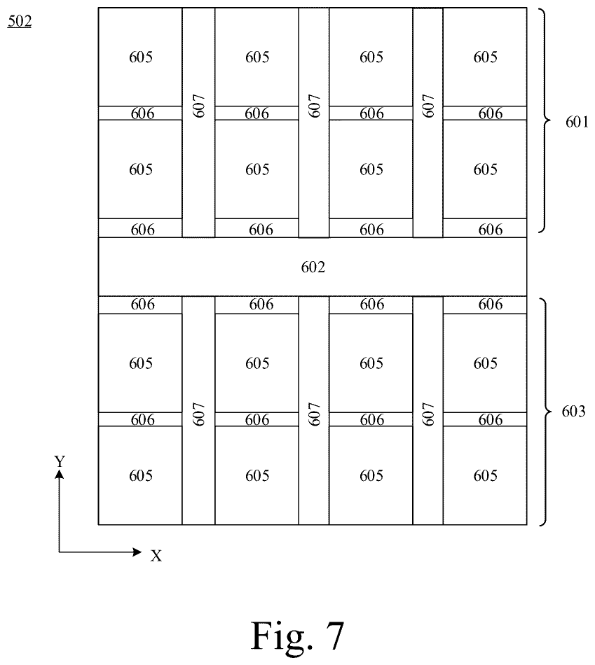

FIG. 7 is a first schematic diagram of the area distribution of a second semiconductor structure 502 according to an example of the present disclosure. It should be noted that, in order to show the relationship between the first memory area 601, the second memory area 603, and the first peripheral area 602 and the second semiconductor structure 502 more clearly, only the second semiconductor structure 502 is shown in FIG. 7 but not the first semiconductor structure.

As shown in FIG. 7, a portion of the second semiconductor structure 502 in the first memory area 601 and the second memory area 603 include first circuit areas 605, second circuit areas 607 and third circuit areas 606, the plurality of first circuit areas 605 are arranged in an array along the second direction and the third direction, and each memory bank corresponds to one first circuit area 605. In an example, as shown in FIG. 7, the second semiconductor structure 502 includes 16 first circuit areas 605, then the memory cell array 503 includes 16 memory banks Bank0-Bank15, each of which corresponds to one first circuit area 605 and includes a plurality of memory blocks. It should be noted that the number of the first circuit areas 605 in FIG. 7 is only an example, and is not intended to limit the number of the first circuit areas 605 in the second semiconductor structure 502 in the example of the present disclosure.

As shown in FIG. 7, a second circuit area 607 is located between adjacent first circuit areas 605 along the third direction, and a third circuit area 606 is located between adjacent first circuit areas 605 along the second direction. A control circuit of each memory block of a corresponding memory bank, such as a sensing amplifier (SA) and a word line driver (WLD), and the like, may be disposed in the first circuit area 605; a control circuit of a corresponding memory bank, such as a row decoding circuit, may be disposed in the second circuit area 607; and a control circuit of a corresponding memory bank, such as a column decoding circuit, may be disposed in the third circuit area 606. A voltage regulation circuit of the charge pump circuit may be disposed in the second semiconductor structure 502 in the first peripheral area 602, and in addition to the voltage regulation circuit described above, a control circuit corresponding to all memory banks, for example, a command buffer, a command decoder, an address buffer, a data input/output buffer, a mode register, etc, may be disposed in the second semiconductor structure 502 in the first peripheral area 602.

In an example of the present disclosure, in a case where the first capacitor structure 504 is located in the first peripheral area 602, the voltage regulation circuit is also located in the first peripheral area 602, that is, the first capacitor structure 504 and the voltage regulation circuit are located in the same area, so that the first capacitor structure 504 is closer to the voltage regulation circuit, and the connection line between the first capacitor structure 504 and the voltage regulation circuit can be shortened.

In some examples, the dynamic random access memory further includes a second peripheral area; where the first memory area, the first peripheral area, and the second memory area are located on a same side of two opposite sides of the second peripheral area along the third direction; the first capacitor structure is located in the second peripheral area; and the third direction is perpendicular to both the first direction and the second direction.

In an example of the present disclosure, the first capacitor structure 504 in the first semiconductor structure 501 is configured as the capacitor of the charge pump circuit, so that the area of the peripheral circuit can be saved, and the first capacitor structure 504 is disposed in an idle area of the first semiconductor structure 501, for example, the first capacitor structure 504 is located in the second peripheral area, so that the idle area of the first semiconductor structure 501 in the second peripheral area can be fully utilized, which is beneficial for reducing the area occupied by the dynamic random access memory and beneficial for the miniaturization development of the dynamic random access memory.

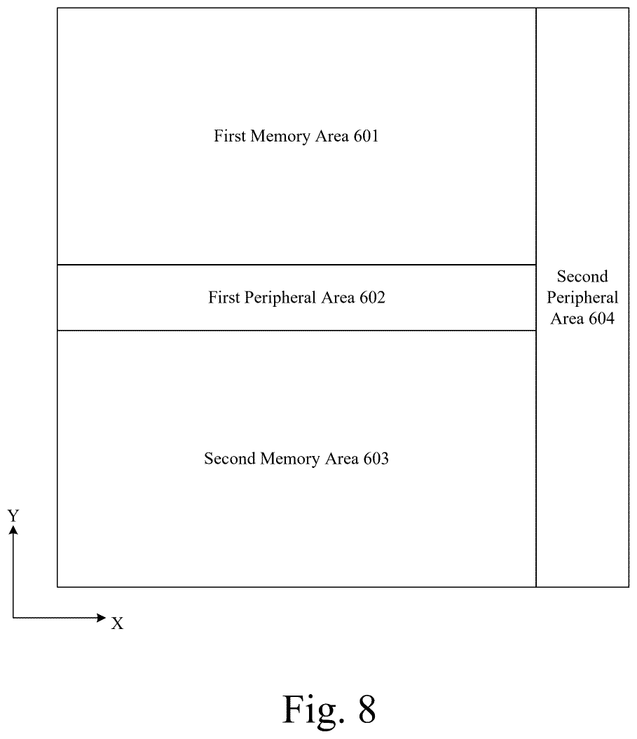

FIG. 8 is a second schematic diagram of the area distribution of a dynamic random access memory according to an example of the present disclosure.

In an example of the present disclosure, as shown in FIG. 8, the dynamic random access memory includes a first memory area 601, a first peripheral area 602, a second memory area 603 arranged along the Y-axis direction, and a second peripheral area 604. The first memory area 601, the first peripheral area 602, and the second memory area 603 are located on a same side of two opposite sides of the second peripheral area 604 along the X-axis direction.

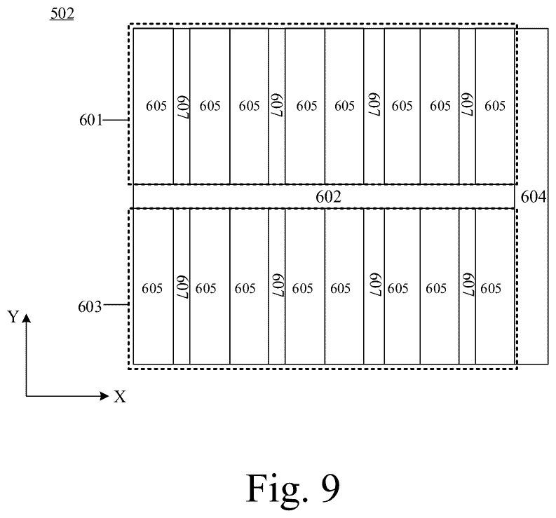

FIG. 9 is a second schematic diagram of the area distribution of a second semiconductor structure 502 according to an example of the present disclosure. It should be noted that, in order to show the relationship between the first memory area 601, the second memory area 603, the first peripheral area 602, and the second peripheral area 604 and the second semiconductor structure 502 more clearly, only the second semiconductor structure 502 is shown in FIG. 9 but not the first semiconductor structure.

As shown in FIG. 9, a portion of the second semiconductor structure 502 in the first memory area 601 and the second memory area 603 include first circuit areas 605 and second circuit areas 607, the plurality of first circuit areas 605 in the first memory area 601 are arranged along the X-axis direction, the plurality of first circuit areas 605 in the second memory area 603 are arranged along the X-axis direction, and each memory bank corresponds to one first circuit area 605. In an example, as shown in FIG. 9, the second semiconductor structure 502 includes 16 first circuit areas 605, then the memory cell array 503 includes 16 memory banks Bank0-Bank15, each of which corresponds to one first circuit area 605 and includes a plurality of memory blocks. It should be noted that the number of the first circuit areas 605 in FIG. 9 is only an example, and is not intended to limit the number of the first circuit areas 605 in the second semiconductor structure 502 in the example of the present disclosure.

In some examples, a voltage regulation circuit 701 is located in the second peripheral area 604.

As shown in FIG. 9, a second circuit area 607 is located between adjacent first circuit areas 605 along the X-axis direction. A control circuit of each memory block of a corresponding memory bank, such as a sense amplification circuit, a word line driving circuit, and the like, may be disposed in the first circuit area 605; and a control circuit of a corresponding memory bank, such as a row decoding circuit, may be disposed in the second circuit area 607. A control circuit of a corresponding memory bank, such as a column decoding circuit, may be provided in the second semiconductor structure 502 in the first peripheral area 602, and a part of a control circuit corresponding to all memory banks may also be disposed in the second semiconductor structure 502 in the first peripheral area 602, for example, a part of a command buffer, a command decoder, an address buffer, a data input/output buffer, a mode register, and the like. A voltage regulation circuit of the charge pump circuit may be disposed in the second semiconductor structure 502 in the second peripheral area 604, and another part of the control circuit corresponding to all the memory banks may also be disposed in the second semiconductor structure 502 in the second peripheral area 604, for example, another part of the command buffer, the command decoder, the address buffer, the data input/output buffer, the mode register, and the like.

In an example of the present disclosure, in a case where the first capacitor structure 504 is located in the second peripheral area 604, the voltage regulation circuit is also located in the second peripheral area 604, that is, the first capacitor structure 504 and the voltage regulation circuit are located in the same region, so that the first capacitor structure 504 is closer to the voltage regulation circuit, and the connection line between the first capacitor structure 504 and the voltage regulation circuit can be shortened.

The dynamic random access memory in an example of the present disclosure may include at least one charge pump circuit, each charge pump circuit includes a voltage regulation circuit and a correspondingly connected capacitor circuit, and the capacitor circuit includes at least one first capacitor structure. The voltage regulation circuit in a same charge pump circuit and the first capacitor structure in the charge pump circuit are located in a same area, for example, both the voltage regulation circuit in the same charge pump circuit and the first capacitor structure in the charge pump circuit may be located in the first peripheral area, or both the voltage regulation circuit in the same charge pump circuit and the first capacitor structure in the charge pump circuit may be located in the second peripheral area. Different charge pump circuits may be located in different areas, or may be located in a same area, for example, a plurality of charge pump circuits may all be located in the first peripheral area, or a plurality of charge pump circuits may all be located in the second peripheral area, or some of the plurality of charge pump circuits are located in the first peripheral area, and the other ones of the plurality of charge pump circuits are located in the second peripheral area.

In some examples, the voltage regulation circuit at least partially overlaps with the first capacitor structure 504 in a view perpendicular to the first direction.

Here, in a case where the first direction is the Z-axis direction in the drawings of the present disclosure, the view perpendicular to the first direction may be construed as the view of the XY plane. Further, when the first direction is a vertical direction, the view perpendicular to the first direction herein may be construed as a top view.

In an example of the present disclosure, the voltage regulation circuit at least partially overlaps with the first capacitor structure 504 in the view perpendicular to the first direction, so that the distance between the voltage regulation circuit and the first capacitor structure 504 is further reduced, and thus further shortening the connection line between the first capacitor structure 504 and the voltage regulation circuit 701.

In some examples, the memory cell array 503 includes a plurality of memory cells, the memory cell includes a transistor structure and a second capacitor structure, and the first capacitor structure 504 has the same structure with the second capacitor structure.

In an example of the present disclosure, a memory cell includes a transistor structure and a second capacitor structure connected with the transistor structure, and the second capacitor structure is configured as a storage capacitor of the memory cell. The first capacitor structure 504 has the same structure with the second capacitor structure, but is not configured as a storage capacitor of the memory cell but as a capacitor of the charge pump circuit, and the first capacitor structure 504 is not connected with the transistor structure but connected with the voltage regulation circuit of the charge pump circuit through a corresponding connection structure. In the forming process of the dynamic random access memory, the first capacitor structure 504 and the second capacitor structure may be formed simultaneously, so that the process time is saved and the process cost is reduced.

In some examples, both the first capacitor structure 504 and the second capacitor structure include a first plate, a second plate, and a dielectric layer between the first plate and the second plate. The material of the dielectric layer may include high dielectric constant (High-K) material, for example, the material of the dielectric layer may include, but is not limited to, aluminum oxide (Al₂O₃), zirconium oxide (ZrO), hafnium oxide (HfO₂), and the like. The material of the first plate may include a conductive material, for example, titanium nitride. The material of the second plate may include a conductive material, for example, titanium nitride or silicon germanium.

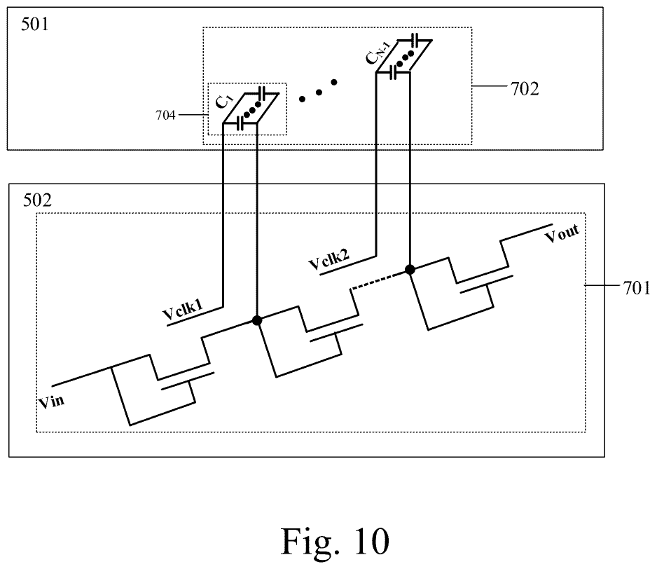

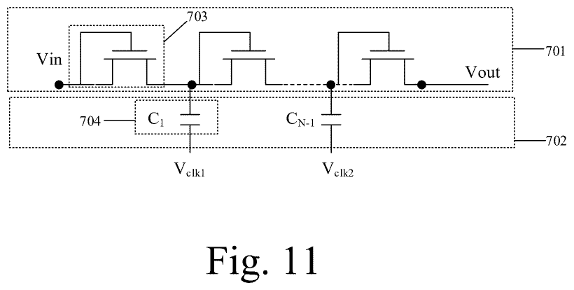

FIG. 10 is a schematic diagram of a relationship between an equivalent circuit of a charge pump circuit and the first semiconductor structure 501 and the second semiconductor structure 502 according to an example of the present disclosure; and FIG. 11 is a schematic diagram of an equivalent circuit of a charge pump circuit according to an example of the present disclosure.

In some examples, as shown in FIG. 10 and FIG. 11, the charge pump circuit includes a voltage regulation circuit 701 and a capacitor circuit 702; the voltage regulation circuit 701 includes a plurality of voltage regulation sub-circuits 703, and the capacitor circuit 702 includes a plurality of capacitor sub-circuits 704.

In some examples, a capacitive sub-circuit 704 at least partially overlaps with a correspondingly connected voltage regulation sub-circuit 703 in the view perpendicular to the first direction.

In an example of the present disclosure, as shown in FIG. 10, the voltage regulation circuit 701 is located in the second semiconductor structure 502, and the capacitor circuit 702 is located in the first semiconductor structure 501. The capacitor circuit 702 is configured to store and transfer charges, and the voltage of the capacitor circuit 702 may be adjusted by the voltage regulation circuit 701.

In an example of the present disclosure, the capacitor sub-circuit 704 at least partially overlaps with the correspondingly connected voltage regulation sub-circuit 703 in the view perpendicular to the first direction, so that the connection between the capacitor sub-circuit 704 and the correspondingly connected voltage regulation sub-circuit 703 can be set to be shorter, and thus the connection line between the first capacitor structure 504 and the voltage regulation circuit 701 can be further shortened.

In some examples, as shown in FIG. 11, the voltage regulation circuit 701 includes N voltage regulation sub-circuits 703 which are sequentially connected in series, wherein an input end of the first voltage regulation sub-circuit 703 is connected with the voltage input end, and an output end of the N-th voltage regulation sub-circuit 703 is connected with the voltage output end; and N is an integer greater than 1.

In an example of the present disclosure, the number N of the voltage regulation sub-circuits 703 may be selected according to voltage requirements, which is not limited in an example of the present disclosure.

In some examples, the voltage regulation sub-circuit 703 includes a diode.

In some examples, the voltage regulation sub-circuit 703 may control a charging and discharging process of the capacitor circuit 702, thereby implementing regulation of the voltage. In addition to the diode in the above examples, the voltage regulation sub-circuit in the examples of the present disclosure may be a metal oxide semiconductor field effect transistor, a complementary metal oxide semiconductor device, a charge transfer switch, or a bipolar transistor.

In some examples, the capacitor circuit 702 includes (N−1) capacitor sub-circuits 704, and the capacitor sub-circuit 704 includes at least one first capacitor structure 504; as shown in FIG. 11, a first end of each of the (N−1) capacitor sub-circuits 704 is connected to an output end of each of first (N−1) voltage regulation sub-circuits 703 in a one-to-one correspondence.

In some examples, as shown in FIG. 11, the second end of an odd-numbered capacitor sub-circuit 704 of the (N−1) capacitor sub-circuits 704 is connected to the first clock signal end, and the second end of an even-numbered capacitor sub-circuit 704 of the (N−1) capacitor sub-circuits 704 is connected to the second clock signal end; and the first clock signal Vclk1 provided by the first clock signal end and the second clock signal Vclk2 provided by the second clock signal end are complementary clock signals.

FIG. 10 and FIG. 11 show a Dickson charge pump circuit, where the Dickson charge pump circuit gradually increases a voltage by periodically changing a connection manner of a capacitor, and mainly uses a clock signal to drive the capacitor to switch between different voltage states, thereby implementing voltage accumulation. The Dickson charge pump circuit shown in FIG. 10 and FIG. 11 is a (N−1) stage Dickson charge pump circuit, and each stage includes one voltage regulation sub-circuit 703 and one capacitor sub-circuit 704. The input voltage is gradually increased by combinations of the voltage regulation sub-circuit 703 and the capacitor sub-circuit 704. Capacitive sub-circuits may be configured to store charge and transfer charge between different phases of the circuit. C₁, C₃ and the like are odd-numbered capacitor sub-circuits, and C₂, C₄ and the like are even-numbered capacitor sub-circuits. C₁ is the capacitor sub-circuit of the first stage, and C_{N-1} is the capacitor sub-circuit of the last stage. The voltage regulation sub-circuit can control the charging and discharging process of the capacitor sub-circuit, and the voltage regulation sub-circuit can be controlled by the first clock signal and the inverted second clock control signal thereof. In each clock cycle, the capacitor sub-circuit is alternately charged and discharged under the control of the first clock signal and the second clock signal, charges of the capacitor sub-circuit are transferred between different stages, so that the voltage is gradually increased, and finally, the charges are transferred to the output capacitor to form a stable high-voltage output.

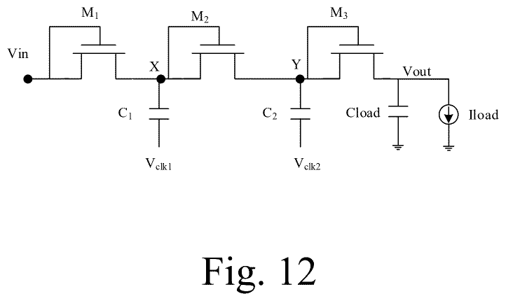

FIG. 12 is a schematic diagram of an equivalent circuit of a Dickson charge pump circuit when N is 3. As shown in FIG. 12, when N is 3, the Dickson charge pump circuit is a two-stage Dickson charge pump circuit, including 2 intermediate nodes X and Y. As shown in FIG. 12, Vin is an input voltage, for example, VDD, Vout is an output voltage, Vclk1 is a first clock signal, Vclk2 is a second clock signal, and Vclk1 and Vclk2 are opposite clock signals, amplitudes of which are, for example, 0~VDD. When the load current Iload is 0, the output voltage of the three-stage charge pump circuit may be calculated by the following formula (1), where VDD is the amplitude of the clock signal, and Vt is the threshold voltage of the diode or the MOSFET.

Vout=2*VDD+Vin−3*Vt (1)

The charging and discharging process of the two-stage Dickson charge pump circuit will be further described below with reference to FIG. 12.

In a first clock cycle, Vclk1 is at a high level, and Vclk2 is at a low level. In a first phase: Vclk1 is at a high level, M₁ is turned on. The input voltage Vin charges C₁ to make its voltage reach Vin. At this time, Vclk1=Vin. In a second phase: Vclk2 is low and M₂ is not turned on. The charge on C₁ remains unchanged. At this time, Vclk2=Vin (from C₁).

In a second clock cycle, Vclk1 is at a low level and Vclk2 is at a high level. In a first phase: Vclk1 is at low level and M₁ is not turned on. The charge on C₁ remains unchanged. At this time, Vclk1=Vin. In a second phase: when Vclk2 is at high level, M₂ is turned on. C₂ is charged from C₁ through M₁, and its voltage reaches 2Vin. At this time, Vclk2=2Vin (from C₂).

In a third clock cycle, Vclk1 is at high level and Vclk2 is at low level. In a first phase: when Vclk1 is at high level, M₁ is turned on. C₁ is again charged from the input voltage Vin, but since the voltage on C₂ is already 2Vin, the voltage on C₁ is now charged to 2Vin. At this time, Vclk1=2Vin. In a second phase: Vclk2 is at low level and M₂ is not turned on. The charge on C₂ remains unchanged. At this time, Vclk2=2Vin (from C₂).

In a fourth clock cycle, Vclk1 is at a low level, and Vclk2 is at a high level. In a first phase: Vclk1 is at low level and M₁ is no turned on. The charge on C₁ remains unchanged. At this time, Vclk1=2Vin. In a second phase: when Vclk2 is at high level, M₂ is turned on. C₂ is charged from C₁ through M₁, and its voltage reaches 3Vin. At this time, Vclk2=3Vin (from C₂).

At the end of each cycle, the output voltage Vout is theoretically the voltage on C_{N-1}, i.e., in the two-stage Dickson charge pump, Vout=3Vin (minus the voltage drop of the voltage regulation circuit).

In some examples, as shown in FIG. 12, the charge pump circuit further includes a load capacitor Cload. The load capacitor Cload is responsible for providing a stable output voltage at the output end of the charge pump circuit to ensure that the load device can obtain a required voltage level. In addition, the load capacitor also helps to reduce voltage fluctuation due to charging and discharging operations in working process of the charge pump circuit, thereby reducing ripple of the output voltage.

In some examples, the load circuit includes at least one first capacitor structure.

Extrapolating to (N−1)-stage Dickson charge pump circuit, when the load current Iload is 0, the output voltage of the charge pump circuit may be calculated by the following formula (2), where VDD is the amplitude of the clock signal, and Vt is the threshold voltage of the voltage regulation sub-circuit. Considering the parasitic capacitance of the node, after the amplitude VDD of the clock signal passes through the capacitor, the actual amplitude voltage VDD′ available at the node may be represented by the following formula (3). The internal resistance of the Dickson charge pump circuit may be represented by the following formula (4), where Rs is the internal resistance of the charge pump circuit, Cs is the parasitic capacitance at the intermediate node such as X/Y or the like, and theoretically Cs at these nodes are equal in magnitude, and f is the frequency of the clock signal. Therefore, if the load current Iload is output and the parasitic capacitance of the intermediate node is considered, the output voltage of the (N−1) stage Dickson charge pump can be represented by the following formula (5), where the last term includes the load current Iload and the frequency f, which is actually the product of the internal resistance Rs of the charge pump circuit and the load current Iload. Thus, an expression of the output voltage of the (N−1) stage Dickson charge pump is given, which is a steady state voltage. The actual output voltage is a continuously fluctuating voltage, and a small ripple can be obtained due to a large load capacitor. The ripple VR of the output voltage may be represented by the following formula (6). When the number of the stages of charge pump, the load current and the load capacitance are fixed, f can be adjusted to improve the performance.

Vout=(N−1)*VDD+Vin−N*Vt (2)

$${V DD}^{′} = ( \frac{C}{C + Cs} ) * V DD \qquad ( 3 )$$

$$Rs = ( \frac{N - 1}{C + Cs} ) * \frac{1}{f} \qquad ( 4 )$$

$$Vout = ( N - 1 ) * ( \frac{C}{C + Cs} ) * V DD + V in - N * V t - \frac{( N - 1 ) * Iload}{( C + Cs ) * f} \qquad ( 5 )$$

$$V R = \frac{Iload}{f * Cload} \qquad ( 6 )$$

In some examples, as shown in FIG. 10, the capacitor sub-circuit 704 includes M first capacitor structures 504 connected in parallel; M is an integer greater than or equal to 2.

In some examples, M is equal to 2.

In an example of the present disclosure, the number of the first capacitor structures in the capacitor sub-circuit is not limited to 2 mentioned in the above examples, and the number of the first capacitor structures in the examples of the present disclosure may be correspondingly set according to the requirements of the current capability required by the charge pump circuit, and the more the number of the first capacitor structures in the capacitor sub-circuit, the larger the current capability that can be provided by the charge pump circuit.

In an example of the present disclosure, the capacitor circuit 702 includes at least one capacitor sub-circuit 704, and the number of the first capacitor structures 504 in different capacitor sub-circuits 704 may be the same or different. Connection manners between the first capacitor structures 504 in different capacitor sub-circuits 704 may be the same or different. The examples of the present disclosure are not limited thereto.

In an example of the present disclosure, the first semiconductor structure 501 and the second semiconductor structure 502 are stacked along the first direction, so that the area occupied by the dynamic random access memory can be saved. The first semiconductor structure 501 and the second semiconductor structure 502 may be formed on the same wafer, or may be respectively formed on different wafers and then connected by a bonding manner. The bonding manner include a hybrid bonding connection (also referred to as “metal/dielectric hybrid bonding connection”), which is a direct bonding technique, such as forming bonds between surfaces without using an intermediate layer such as solder or adhesive, and can obtain metal-metal bonding and dielectric-dielectric bonding simultaneously. It should be noted that the “bonding” in the examples of the present disclosure may be any suitable bonding technology, such as the hybrid bonding mentioned above, or, for example, anodic bonding, fusion bonding, transfer bonding, adhesive bonding, eutectic bonding, and the like. Hereinafter, the hybrid bonding connection is taken as an example for description.

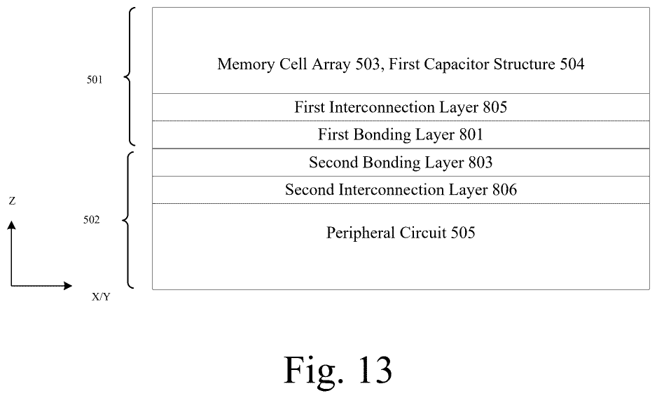

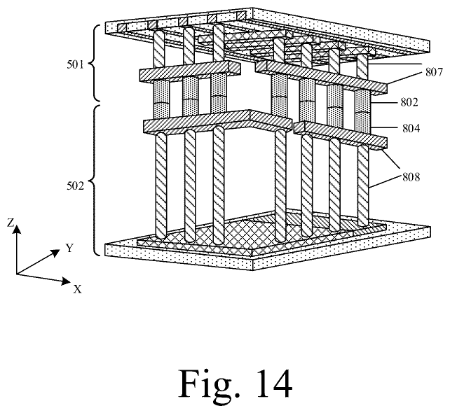

In some examples, as shown in FIG. 13 and FIG. 14, the first semiconductor structure 501 further includes a first bonding layer 801 including a first bonding structure 802, where the first bonding layer 801 is located between the memory cell array 503 and the second semiconductor structure 502, and located between the first capacitor structure 504 and the second semiconductor structure 502; and the second semiconductor structure 502 further includes a second bonding layer 803, which includes a second bonding structure 804 and is located between the peripheral circuit 505 and the first semiconductor structure 501.

The first semiconductor structure 501 and the second semiconductor structure 502 in an example of the present disclosure are bonded through the first bonding layer 801 and the second bonding layer 803. In some examples, the first bonding layer 801 further includes a first dielectric layer in which the first bonding structure 802 is located, and the second bonding layer 803 further includes a second dielectric layer in which the second bonding structure 804 is located. The materials of the first dielectric layer and the second dielectric layer include, but are not limited to, silicon oxide or silicon nitride. The materials of the first bonding structure 802 and the second bonding structure 804 include a conductive material, such as at least one of a doped semiconductor material (e.g., doped silicon, doped germanium, etc.), a conductive metal nitride (e.g., titanium nitride, tantalum nitride, etc.), a metal material (e.g., aluminum, copper, tungsten, titanium, tantalum, etc.), and a metal semiconductor compound (e.g., tungsten silicide, cobalt silicide, titanium silicide, etc.).

In some examples, as shown in FIG. 13 and FIG. 14, the first semiconductor structure 501 further includes a first interconnection layer 805, which is located between the first capacitor structure 504 and the first bonding layer 801 and includes a first interconnection structure 807; and the second semiconductor structure 502 further includes a second interconnection layer 806, which is located between the voltage regulation circuit 701 and the second bonding layer 803 and includes a second interconnection structure 808.

In an example of the present disclosure, as shown in FIG. 13, the first interconnection layer 805 is located between the memory cell array 503 and the first bonding layer 801 and located between the first capacitor structure 504 and the first bonding layer 801; and the second interconnection layer 806 is located between the peripheral circuit 505 and the second bonding layer 803.

In some examples, the first interconnect structure 807 and the second interconnect structure 808 include, for example, conductive lines extending in a direction perpendicular to the first direction and contact structures extending in the first direction, and the first interconnect structure 807 and the second interconnect structure 808 may be formed in one or more interlayer dielectric (ILD) layers. The materials of the first interconnect structure 807 and the second interconnect structure 808 may include the conductive material. The ILD layers in the first interconnect layer 805 and the second interconnect layer 806 may include the dielectric material including, but not limited to, silicon oxide, silicon nitride, silicon oxynitride, low-k dielectrics, or any combination thereof.

In some examples, as shown in FIG. 13 and FIG. 14, the first semiconductor structure 501 further includes a first interconnection structure 807 located between the first capacitor structure 504 and the first bonding layer 801; the second semiconductor structure 502 further includes a second interconnection structure 808 located between the voltage regulation circuit 701 and the second bonding layer 803; and the first capacitor structure 504 is connected to the voltage regulation circuit 701 through the first interconnection structure 807, the first bonding structure 802, the second bonding structure 804, and the second interconnection structure 808.

In an example of the present disclosure, the first capacitor structure 504 is not connected with the transistor structure, the first capacitor structure 504 is connected with the first interconnection structure 807, and the first capacitor structure 504 located in the first semiconductor structure 501 is connected with the voltage regulation circuit 701 of the charge pump circuit located in the second semiconductor structure 502 through the first interconnection structure 807, the first bonding structure 802, the second bonding structure 804, and the second interconnection structure 808.

Based on the foregoing dynamic random access memory, an example of the present disclosure further provides a memory system including a memory controller and a dynamic random access memory according to any one of the above examples; the memory controller is coupled with the dynamic random access memory and configured to control the dynamic random access memory.

For the memory system herein, reference may be made to the foregoing FIG. 1A, FIG. 1B, FIG. 2A, and FIG. 2B and corresponding descriptions, and details are not described herein again for brevity.

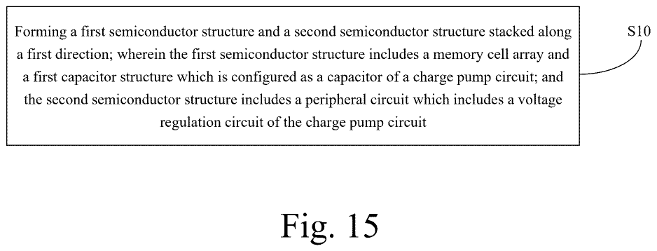

Based on the foregoing dynamic random access memory, an example of the present disclosure further provides a forming method of a dynamic random access memory, and FIG. 15 is a schematic flowchart of the forming method for the dynamic random access memory according to an example of the present disclosure. As shown in FIG. 15, the forming method of the dynamic random access memory includes the following operations: operation S10: forming a first semiconductor structure and a second semiconductor structure stacked along a first direction; wherein the first semiconductor structure includes a memory cell array and a first capacitor structure which is configured as a capacitor of a charge pump circuit; and the second semiconductor structure includes a peripheral circuit which includes a voltage regulation circuit of the charge pump circuit.

In an example of the present disclosure, the first semiconductor structure and the second semiconductor structure may be formed on a same wafer, or on different wafers, which is not limited in the example of the present disclosure.

In some examples, forming the first semiconductor structure and the second semiconductor structure stacked along the first direction includes: forming the first capacitor structure while forming a second capacitor structure of the memory cell of the memory cell array.

In an example of the present disclosure, the first capacitor structure is formed while the second capacitor structure of the memory cell is formed, so that the process time can be saved and the process cost can be reduced.

The features disclosed in the several device examples provided by the present disclosure may be arbitrarily combined without conflict to obtain new device examples.

The methods disclosed in the several method examples provided by the present disclosure may be arbitrarily combined without conflict to obtain new method examples.

The above description are only implementations of the present disclosure, but the protection scope of the present disclosure is not limited thereto, and changes or replacements that may be easily conceived by any person skilled in the art within the technical scope of the present disclosure should be covered within the protection scope of the present disclosure.

What is claimed is:

1. A dynamic random access memory, comprising:
a first semiconductor structure and a second semiconductor structure that are stacked along a first direction,
wherein the first semiconductor structure comprises a memory cell array and a first capacitor structure configured as a capacitor of a charge pump circuit, and
wherein the second semiconductor structure comprises a peripheral circuit that comprises a voltage regulation circuit of the charge pump circuit.

2. The dynamic random access memory of claim 1, wherein the dynamic random access memory comprises a first memory area, a first peripheral area, and a second memory area that are arranged along a second direction, and
wherein the first peripheral area is located between the first memory area and the second memory area, the memory cell array is located in the first memory area and the second memory area, and the second direction is perpendicular to the first direction.

3. The dynamic random access memory of claim 2, wherein the first capacitor structure is located in the first peripheral area.

4. The dynamic random access memory of claim 3, wherein the voltage regulation circuit is located in the first peripheral area.

5. The dynamic random access memory of claim 2, wherein the dynamic random access memory further comprises a second peripheral area; and
wherein the first memory area, the first peripheral area and the second memory area are located on a same side of two opposite sides of the second peripheral area along a third direction, the first capacitor structure is located in the second peripheral area, and the third direction is perpendicular to both the first direction and the second direction.

6. The dynamic random access memory of claim 5, wherein the voltage regulation circuit is located in the second peripheral area.

7. The dynamic random access memory of claim 1, wherein the voltage regulation circuit at least partially overlaps with the first capacitor structure in a view perpendicular to the first direction.

8. The dynamic random access memory of claim 1, wherein the memory cell array comprises a plurality of memory cells, and
wherein the memory cell comprises a transistor structure and a second capacitor structure, and the first capacitor structure and the second capacitor structure have a same structure.

9. The dynamic random access memory of claim 1, wherein the charge pump circuit comprises the voltage regulation circuit and a capacitor circuit,
wherein the voltage regulation circuit comprises a plurality of voltage regulation sub-circuits, and the capacitor circuit comprises a plurality of capacitor sub-circuits, and
wherein a capacitor sub-circuit of the plurality of capacitor sub-circuits at least partially overlaps with the correspondingly connected voltage regulation sub-circuit of the plurality of voltage regulation sub-circuits in a view perpendicular to the first direction.

10. The dynamic random access memory of claim 9, wherein the voltage regulation circuit comprises N voltage regulation sub-circuits sequentially connected in series, and
wherein an input end of a first voltage regulation sub-circuit is connected to a voltage input end, and an output end of an N-th voltage regulation sub-circuit is connected to a voltage output end, and N is an integer greater than 1.

11. The dynamic random access memory of claim 10, wherein a voltage regulation sub-circuit of the N voltage regulation sub-circuits comprises a diode.

12. The dynamic random access memory of claim 10, wherein the capacitor circuit comprises (N−1) capacitor sub-circuits, and the capacitor sub-circuit comprises at least one first capacitor structure, and
wherein a first end of each of the (N−1) capacitor sub-circuits is connected to an output end of each of first (N−1) voltage regulation sub-circuits in a one-to-one correspondence.

13. The dynamic random access memory of claim 12, wherein a second end of an odd-numbered capacitor sub-circuit of the (N−1) capacitor sub-circuits is connected to a first clock signal end, and a second end of an even-numbered capacitor sub-circuit of the (N−1) capacitor sub-circuits is connected to a second clock signal end, and
wherein a first clock signal provided by the first clock signal end and a second clock signal provided by the second clock signal end are complementary clock signals.

14. The dynamic random access memory of claim 12, wherein the capacitor sub-circuit comprises M first capacitor structures connected in parallel, and M is an integer greater than or equal to 2.

15. The dynamic random access memory of claim 14, wherein M is equal to 2.

16. The dynamic random access memory of claim 1, wherein:
the first semiconductor structure further comprises a first bonding layer that comprises a first bonding structure, and the first bonding layer is located between the memory cell array and the second semiconductor structure and between the first capacitor structure and the second semiconductor structure, and
the second semiconductor structure further comprises a second bonding layer that comprises a second bonding structure, and the second bonding layer is located between the peripheral circuit and the first semiconductor structure.

17. The dynamic random access memory of claim 16, wherein:
the first semiconductor structure further comprises a first interconnection structure located between the first capacitor structure and the first bonding layer,
the second semiconductor structure further comprises a second interconnection structure located between the voltage regulation circuit and the second bonding layer, and
the first capacitor structure is connected to the voltage regulation circuit through the first interconnection structure, the first bonding structure, the second bonding structure, and the second interconnection structure.

18. A memory system, comprising:
a memory controller; and
a dynamic random access memory, comprising:
a first semiconductor structure and a second semiconductor structure that are stacked along a first direction;
wherein the first semiconductor structure comprises a memory cell array and a first capacitor structure that is configured as a capacitor of a charge pump circuit, and the second semiconductor structure comprises a peripheral circuit that comprises a voltage regulation circuit of the charge pump circuit,
wherein the memory controller is coupled with the dynamic random access memory and configured to control the dynamic random access memory.

19. A method of forming a dynamic random access memory, comprising:
forming a first semiconductor structure and a second semiconductor structure that are stacked along a first direction,
wherein the first semiconductor structure comprises a memory cell array and a first capacitor structure that is configured as a capacitor of a charge pump circuit, and the second semiconductor structure comprises a peripheral circuit that comprises a voltage regulation circuit of the charge pump circuit.

20. The method of claim 19, wherein the forming the first semiconductor structure and the second semiconductor structure that are stacked along the first direction comprises:
forming the first capacitor structure while forming a second capacitor structure of a memory cell of the memory cell array.
